(19) United States
(12) Patent Application Publication
(10) Pub. No.: US 2015/0029681 A1
(43) Pub. Date: Jan. 29, 2015

(54) FLEXIBLE COMPOSITE, PRODUCTION THEREOF AND USE THEREOF

(71) Applicants: Helmut MACK, Traunstein (DE); Philipp ALBERT, Loerrach (DE); Bjoern BORUP, Frankfurt (DE); Anil K. SAXENA, Morris Plains, NJ (US)

(72) Inventors: Helmut MACK, Traunstein (DE); Philipp ALBERT, Loerrach (DE); Bjoern BORUP, Frankfurt (DE); Anil K. SAXENA, Morris Plains, NJ (US)

(73) Assignee: EVONIK INDUSTRIES AG, Essen (DE)

(21) Appl. No.: 14/328,887

(22) Filed: Jul. 11, 2014

Related U.S. Application Data
(60) Provisional application No. 61/859,584, filed on Jul. 29, 2013.

(51) Int. Cl. H05K 1/02; C23C 16/24; C23C 16/32; H05K 1/03; C23C 16/40; C23C 16/50; H01B 17/00; H01B 17/50; C23C 16/06; C23C 16/34

(52) U.S. Cl. CPC H05K 1/028; C23C 16/06; C23C 16/24; C23C 16/325; C23C 16/345; C23C 16/402; C23C 16/407; C23C 16/50; H01B 17/005; H01B 17/50; H05K 1/0306
USPC 361/748; 428/688; 428/457; 428/697; 428/696; 428/698; 428/702; 428/336; 428/523; 428/412; 428/423.1; 428/480; 428/447; 428/201; 428/426; 428/474.4; 428/473.5; 427/576; 427/577; 427/578; 427/579

(57) ABSTRACT

A flexible composite comprising a plastic foil, having an upper and a lower surface, and at least one dielectric barrier layer against gases and liquids which is applied directly to at least one of the surfaces by plasma-enhanced thermal vapor deposition and comprises an inorganic vapor-depositable material, is provided. The flexible composite can be used for constructing flexible circuits or displays and has a high barrier effect with regard to oxygen and/or water vapor.

### CROSS REFERENCE TO RELATED APPLICATIONS

This application claims priority to U.S. Provisional Application No. 61/859,584, filed Jul. 29, 2013, the disclosure of which is incorporated herein by reference in its entirety.

### BACKGROUND OF THE INVENTION

1. Field of the Invention

The present invention relates to a flexible composite useful in the field of flexible electronics, especially in the production of flexible electronic circuits, flexible circuit boards, flexible displays, for example flexible LCD displays or flexible OLED displays, flexible light-emitting elements, for example flexible LEDs or flexible OLEDs, flexible power generators or stores, such as flexible solar cells or flexible rechargeable batteries, or flexible flat cables.

2. Description of the Related Art

Flexible electronics, also known as flexible circuits, are a technology for assembling electronic circuits by mounting electronic devices on flexible polymeric substrates. Foils of high temperature resistant polymers or foils of transparent polymers are used for example.

Flexible circuits may also be foils to which printed circuits, such as silver, copper, aluminum or platinum tracks, have been applied by imaging processes, for example by screen printing or by inkjet printing. Flexible electronic circuits can be produced using the same structural components as for rigid circuit boards and can be adapted into a desired shape during production or can be bent during use. These flexible printed circuits (FPCs) can be produced using a photolithographic technology. An alternative way to produce circuits on flexible foil or to produce flexible flat cables (FFCs) is to laminate very thin strips of metal between two layers of plastics foil, such as polyethylene terephthalate (PET). For this, these PET layers are coated with a thermosetting adhesive which is activated during lamination. FPCs and FFCs exhibit a series of advantages for many applications:
it is possible to produce fixedly mounted electronic subassemblies where electric connections are required in 3 axes, for example in cameras
it is possible to produce electric connections where the subassembly has to exhibit flexibility during the intended use, for example in mobile phones
it is possible to construct electric connections between subassemblies in order to replace cable harnesses which are heavier and bulkier, for example in cars, ships, aircraft, rockets or satellites, and
it is possible to produce electric connections in environments where board thickness or space constraints are the determining factors.

Flexible circuits can be vulnerable to chemical attacks from the environment. For instance, oxygen or water vapor can have an adverse effect on the life of micro-electronic circuitries. This holds especially when these circuits are used in chemically aggressive environments. There has been no shortage of attempts to isolate electronic circuits from the environment in order that their stability and longer functionability may be ensured. One example thereof is the encapsulation of integrated circuitries in resin. In the case of flexible circuits, an approach of this kind would have an adverse effect on the flexibility of the product. There have also already been attempts to use thin glass foils for enclosing flexible circuits. The disadvantage with this is that the flexibility of these glass foils is frequently insufficient. As the laminate is bent, especially to different curvatures, these products often fail and the glass foils crack and lose their original function.

A further field of potentially huge user benefit is that of flexible transparent displays, flexible transparent light-emitting elements or flexible photovoltaic elements. These elements could be brought into any desired shape for use and would allow designers to open up completely new fields of use. Thus, the hitherto employed bar shape of communication devices, such as smartphones, could be broken up in this way. In addition, it would also be possible to produce parts in a completely new shape which require a barrier and/or weatherproof coating. Parts comprising plastic are generally simpler to shape than glass parts. Glass-plastic composite parts can be produced in entirely novel shapes. In automobile construction in particular, flexible displays or light-emitting elements could be smoothly integrated in the design language of the interior space. These kinds of flexible displays and light-emitting elements or photovoltaic elements could be used/transported in a space-saving manner, for example in rolled form. The electronics used in these elements are water and oxygen sensitive and therefore have to be protected. This could be accomplished by encapsulation with plastics foils. However, no plastics foils known to date have a sufficiently high barrier function for oxygen and water vapor while being extremely flexible at the same time and capable of being infinitely often folded or shaped in use without losing their function as a result.

Therefore, an object of the present invention is to provide a flexible plastic foil having good barrier properties to oxygen and water.

### SUMMARY OF THE INVENTION

This and other objects are provided by the present invention, the first embodiment of which includes a flexible composite barrier against gases and liquids, comprising: a plastic foil having an upper and a lower surface; and a dielectric barrier layer on at least one surface of the plastic foil; wherein the dielectric barrier layer comprises an inorganic vapor depositable material, and the dielectric barrier layer is applied directly to the at least one surface of the foil by plasma-enhanced thermal vapor deposition.

In an aspect of the first embodiment, the composite barrier comprises a dielectric barrier layer on each of the upper and lower surfaces; wherein each of the barrier layers is applied by plasma-enhanced thermal vapor deposition.

In a further aspect, the inorganic vapor-depositable material of the dielectric barrier layer is selected from the group consisting of aluminum, gold, silver, chromium, nickel, copper, silicon, gallium, alumina, silica, silicon nitride, silicon carbide, titania, zirconia, indium-tin oxide, fluorine-doped tin oxide, indium-gallium-tin oxide, cadmium telluride, copper-indium-gallium-selenium-sulfur compounds and a vapor-depositable glass material.

Surprisingly, a composite formed with a plastic foil and endowed with a barrier layer has been found not to have the disadvantages of existing solutions and to be very useful as a barrier foil for flexible electronics.

This composite may be thermally stable, may display an extremely high barrier effect against oxygen and water vapor, is resistant to moisture, can be homogeneously applied or laminated, has smooth surfaces, exhibits excellent inter-adherence of the layers, is flexible and scratchproof, and may be transparent.

The flexible composite according to the present invention provides a flexible barrier layer against gases and liquids, particularly against oxygen and water vapor.

In another embodiment, the present invention includes an electric component comprising the flexible composite barrier of the present invention, wherein the electric component is selected from the group consisting of an electronic component, an electro-optical component, an electromechanical component, a micromechanical component and a flexible electric connection.

The forgoing description is intended to provide a general introduction and summary of the present invention and is not intended to be limiting in its disclosure unless otherwise explicitly stated. The presently preferred embodiments, together with further advantages, will be best understood by reference to the following detailed description taken in conjunction with the accompanying drawings.

### DETAILED DESCRIPTION OF THE PREFERRED EMBODIMENTS

As used herein, the words “a” and “an” and the like carry the meaning of “one or more.” The phrases “selected from the group consisting of,” “chosen from,” and the like include mixtures of the specified materials. Terms such as “contain(s)” and the like are open terms meaning ‘including at least’ unless otherwise specifically noted. Where a numerical limit or range is stated, the endpoints are included. Also, all values and subranges within a numerical limit or range are specifically included as if explicitly written out.

In a first embodiment, the present invention includes a flexible composite barrier against gases and liquids, comprising: a plastic foil having an upper and a lower surface; and a dielectric barrier layer on at least one surface of the plastic foil; wherein the dielectric barrier layer comprises an inorganic vapor depositable material, and the dielectric barrier layer is applied directly to the at least one surface of the foil by plasma-enhanced thermal vapor deposition.

In an aspect of the first embodiment, the composite barrier comprises a dielectric barrier layer on each of the upper and lower surfaces; wherein each of the barrier layers is applied by plasma-enhanced thermal vapor deposition.

The plasma-enhanced thermal vapor deposition of dielectric layers onto surfaces of different substrates is conventionally known. Examples of processes of this type are described in WO 2011/009444 A1, in WO 2010/009719 A1 and in WO 2011/035783 A1. Combinations of plastics foils with dielectric layers are not described in these references. It was particularly surprising that the flexible plastics foil forms an extremely firmly adhering combination with the vapor-deposited dielectric layer, this combination impairing neither the flexibility of the initial foil nor its deployment in the production and use of flexible electronics. The composite of the present invention makes it possible to achieve very good protection of enclosed products, especially flexible electronic products, such as flexible electronic circuits, flexible circuit boards, flexible displays, flexible light-emitting elements, flexible power generators or stores or flexible flat cables, with regard to oxygen and water vapor.

One aspect of the invention provides a process for producing a coating on a plastics foil, said process comprising the steps of: providing a plastics foil having at least one surface to be coated and producing a coating on the plastics foil's surface to be coated by depositing at least one inorganic vapor-depositable material on the plastics foil's surface to be coated, by thermal vaporization of the at least one inorganic vapor-depositable material. All or only some of the coating can be produced using plasma-enhanced thermal electron beam vaporization. This method of application is particularly gentle. Many plastics have only limited thermal stability. The advantage of this method consists in the fact that application may take place at temperatures of less than 100° C.

A further aspect of the invention relates to a coated plastic foil, especially obtained by the preceding process, where at least one surface exhibits a coating consisting at least partly of at least one inorganic vapor-depositable material. Transparent layers of glass which range in thickness from a few nanometers to several micrometers may be applied in this way to combine with the plastic foil to form a flexible and also transparent composite.

The inorganic vapor-depositable material used may in principle be any inorganic material vaporizable under the conditions of plasma-enhanced thermal electron beam vaporization, especially materials based on metals, semiconductors, metal oxides, metal carbides or metal nitrides. Preferred examples of metals include aluminum, gold, silver, chromium, nickel or copper; preferred examples of semiconductors include silicon, gallium, cadmium telluride or copper-indium-gallium-selenium-sulfur compounds; such as copper-indium-gallium diselenide or copper-indium disulfide; preferred examples of metal oxides include alumina, silica, silicon nitride, silicon carbide, titania, zirconia, indium-tin oxide, fluorine-doped tin oxide, indium-gallium-tin oxide or especially vapor-depositable glass material. Silicate glass may be used with preference and borosilicate glass with particular preference.

The invention provides an efficient way to create individually designed whole-area or structured coatings on a plastic foil for various applications by depositing at least one inorganic vapor-depositable material. This material makes it possible to provide configured coatings of plastic foils for various applications.

The different inorganic vapor-depositable materials may be used to achieve individual or combined advantages whereby different optimizations are possible depending on the inorganic vapor-depositable material used and the particular application. Thus, vapor-deposited layers obtained from the one-component system silica generally have a higher optical transmission, especially in the ultraviolet wavelength region, as compared with layers obtained from vapor-depositable glass material in similar thickness. Similarly, the breakdown voltage is higher for silica. Alumina is notable for a high resistance to scratching and a high optical refractive index. Titania has a very high optical refractive index. Silicon nitride has a high breakdown voltage and additionally has a high optical refractive index compared with vapor-deposited glass. The latter is, however, very useful for production of surface layers having a high oxygen and water vapor barrier function.

The inorganic vapor-depositable materials enable a comparatively gentle coating of the plastic foil by plasma-enhanced thermal electron beam vaporization.

Melting temperatures of borosilicate glass useful as vapor-depositable glass material for example are about 1300° . The corresponding values are about 1713° C. in the case of silica, about 2050° C. in the case of alumina, about 1843° C. in the case of titania, about 1900° C. in the case of silicon nitride and more than 2300° C. in the case of silicon carbide.

Use of plasma-enhanced thermal electron beam vaporization of inorganic vapor-depositable material facilitates an optimized form of layer deposition. Plasma-enhanced thermal vaporization may be individually modulated according to the desired application in order to achieve desired layer properties when producing the coating on the plastics foil. Plasma enhancement also makes it possible, for example, to control and optimize the layer adherence and the intrinsic compressive or tensile stresses in the layer. It is further possible to influence the stoichiometry of the vapor-deposited layer.

The coating on the plastic foil may have a single- or multi-layered construction in the various embodiments of the invention. In a multi-layer construction, it may be possible for both surfaces of the plastics foil to be coated and/or for two or more layers to be vapor deposited on one surface. It may be possible in such an embodiment for at least one sub-layer to be formed from a first vapor-deposited material and for at least one further sub-layer to be formed from some other vapor-deposited material. For example, a first sub-layer may be formed from silica, then a layer may be formed thereon from alumina or from borosilicate glass.

In one embodiment, one or more sub-layers of the coating which are deposited by plasma-enhanced thermal electron beam vaporization may be combined with one or more further sub-layers formed using other methods of preparation, for example sputtering or chemical vapor deposition (CVD). The one or more further sub-layers of the coating can be processed before and/or after the deposition of the one or more sub-layers.

Plasma enhancement promotes high quality on the part of the vapor-deposited layer. Good compaction and hence hermetic properties are accordingly achievable. Owing to the improved growth of a layer, defects are minimal. The substrate to be coated does not need to be preheated. A coating process of this type is also known as an IAD cold-coating process. One particular advantage thereof is the high deposition rate which can be achieved to allow process times in production to be optimized as a whole.

Vapor deposition processes of the conventional type require strong preheating of the substrates if high layer qualities are to be achieved. This leads to an increased desorption of condensing particles and hence reduces the attainable rate of vapor deposition. The plasma enhancement has the additional benefit that the vapor lobe can be oriented using the plasma jet in order to achieve an anisotropic landing pattern for the vaporized particles on the plastics surface to be coated. The result is that layer deposition may be achieved without so-called links. Links are unintended connections between different regions on the plastic foil's surface to be coated.

Preferred forms of the process may have one or more of the following process features. In one incarnation, the plasma-enhanced thermal electron beam vaporization process may be carried out with vapor-deposition rates of about 20 nm/min to about 2 μm/min. Use of an oxygen, nitrogen and/or argon plasma can be contemplated. Alternatively or additionally, the process step of thermal vaporization may be preceded by a pretreatment to activate and/or clean the plastic surface to be coated. The pretreatment can be carried out by using a plasma, especially an oxygen, nitrogen and/or argon plasma. Preferably, the pretreating is carried out in situ, i.e. directly in the coating rig prior to thermal vaporization.

In one possible advantageous embodiment of the invention, the step of thermally vaporizing the at least one inorganic vapor-depositable material comprises a step of co-vaporization from two or more vaporization sources. By co-vaporization from two or more vaporization sources, identical or different materials may be deposited.

Preferably, in one further development of the invention, the step of producing a coating on the plastic foil's surface to be coated is carried out two or more times.

In a further advantageous incarnation of the invention, the coating may be produced in two or more areas of the plastic foil. For example, the coating can be produced on the top and the bottom of the plastic foil. Coating deposition on the top and bottom can take place in concurrent or successive operations.

In a preferred further development of the invention, a structured coating is applied to at least one surface of the plastic foil and the structures of the structured coating are at least partly infilled. Electrically conducting and/or transparent materials may be used to at least partly infill the structured coating.

In one advantageous embodiment of the invention, at least one conducting region is produced on at least one surface of the plastics foil. The at least one conducting region may be used for example to produce one or more conductor tracks. These may be situated on the plastics foil's surface remote from the coating or directly on that surface of the plastics foil which is covered with the coating, or on both sides of the plastics foil.

In a further advantageous embodiment of the invention, a bond layer may be formed on the structured coating. The bond layer comprises for example a seed layer for a subsequent metallization and/or a layer of adhesive.

Preferably, in one aspect of the invention, the coating may be formed as a multi-ply coating on at least one surface of the plastic foil. In one embodiment, the multi-ply coating is formed using layers of vapor-depositable glass material, especially borosilicate glass, or using silica and a vapor-depositable glass material, or using silica and alumina, in which case the sub-layer of the vapor-depositable glass material or the alumina forms a cover layer on the silica. One possibility in this connection is to produce one or more sub-layers using deposition technologies other than thermal vaporization, sputtering for example.

In one advantageous incarnation of the invention, the coating is formed in a layer thickness of 0.05 μn to 100 μm, preferably in a layer thickness of 0.1 μm to 50 μm and more preferably in a layer thickness between about 0.1 μm and 1 μm. Layer thickness for the purposes of this invention is determined using a profilometer (from Veeco Metrology Group for example).

In one further development of the invention, the surface of the plastic foil has a temperature of not more than about 120° C., preferably not more than about 100° C., during deposition of the at least one inorganic vapor-depositable material. This low substrate temperature is particularly advantageous for coating thermally sensitive materials. Use of plasma-enhanced thermal electron beam vaporization in one incarnation ensures sufficient densification on the part of the layers produced without any need for post-annealing.

According to the invention, a plastic foil is used as substrate. Any desired plastic may be utilized in principle, such as a thermosetting or a thermoplastic plastic.

The plastic may generally be synthetic organic polymers. Copolymers can be used as well as homopolymers. Foils composed of mixtures of organic polymers or foils composed of plastic composites may also be used.

The plastic foils used may be constructed of partly crystalline and/or amorphous organic polymers. Transparent foils composed of organic polymers may be used with preference. In the present invention, transparency is to be understood as meaning in the context of this description that in the wavelength range from 380 nm to 780 nm the foils have a transmissivity for electromagnetic radiation of not less than 80%, preferably not less than 90% and most preferably from 95% to 100% of electromagnetic radiation incident upon a foil surface.

Foils composed of amorphous organic polymers may be used with particular preference.

The thickness of the plastic foils used according to the present invention can vary within wide limits. Foil thickness must be chosen so as to ensure a requisite flexibility for the intended use. Typical thicknesses for the plastic foils vary in the range from 0.5 μm to 5 mm, especially in the range from 1 μm to 1 mm and most preferably in the range from 5 μm to 500 μm.

The polymers used according to the present invention may be products obtained in any desired manner, for example products produced by free-radical chain growth addition polymerization, by condensation polymerization or by polyaddition.

Examples of polymer types used with preference include polyolefins, such as polyethylenes, polypropylenes, polymers derived from polycyclic olefins, for example cycloolefin copolymers, for example derived from norbornene and ethylene.

Further examples of polymer types used with preference include polyvinyl halides or polyvinylidene halides, such as polyvinyl chloride, polyvinylidene chloride or polyvinylidene fluoride.

Further examples of polymer types used with preference include polyvinylaromatics, such as polystyrene or copolymers of styrene with other ethylenically unsaturated monomers.

Further examples of polymer types used with preference include polyacrylic esters or polymethacrylic esters (“poly(meth)acrylates”), polyvinyl ethers, polyvinylcarboxylic esters, polytetrahaloethylene, such as polytetrafluoroethylene, or acrylonitrile homo- or copolymers.

Further examples of polymer types used with preference include polyoxymethylene homo- or copolymers.

Further examples of polymer types used with preference include polyamides, such as polyamides derived from aliphatic or aromatic dicarboxylic acids or from aromatic or aliphatic diamines and also from aromatic or aliphatic amino carboxylic acids. Examples thereof are aliphatic polyamides derived from adipic acid and 1,6-hexamethylenediamine, from sebacic acid and 1,6-hexamethylenediamine, from caprolactam, or from terephthalic acid and from 1,4-diaminobenzene.

Further examples of polymer types used with preference are polyesters including the polycarbonates, such as polyesters derived from aliphatic or aromatic dicarboxylic acids and from aromatic or aliphatic dialcohols and also from aromatic or aliphatic hydroxy carboxylic acids or from aliphatic or aromatic dialcohols or from phosgene. Examples thereof are polyesters derived from terephthalic acid and ethylene glycol, from phthalic acid and ethylene glycol, from terephthalic acid and 1,4-butanediol, from hydroxybenzoic acid or from bisphenol A and phosgene.

Particular preference is given to polycarbonates coated with scratchproof vapor-deposited glass material. These are very useful as scratchproof components for automobile construction for example.

Further examples of polymer types used with preference are polyurethanes, such as polyurethanes derived from aliphatic or aromatic diisocyanates and from aromatic or aliphatic dialcohols. Examples thereof are polyurethanes derived from phenyl diisocyanate and from polyalkylene glycols.

Further examples of polymer types used with preference are polyalkylene glycols, such as polyethylene glycols, polypropylene glycols or polybutylene glycols, or polyvinyl alcohols. These polymers, as will be appreciated, have to be chosen as regards molecular weight and/or viscosity such that foils can be formed therefrom.

Further examples of polymer types which may be used with preference are poly(organo)siloxanes, such as poly(dimethyl)siloxane. As will be appreciated, these polymers also have to be chosen as regards molecular weight and/or viscosity such that foils can be formed therefrom.

Foils composed of high temperature resistance polymers are used as substrates with very particular preference. This is to be understood in the context of this description as meaning that the polymers are suitable for sustained use temperatures of 150 to 250° C. Brief temperature spikes of up to 400° C. are possible, for example in the deployment of CVD or PACVD processes.

High temperature resistant polymer classes used with particular preference are
fluoropolymers such as polytetrafluoroethylene or perfluoroalkoxyalkane
polyphenylenes
polyaryls where aromatic rings are linked via oxygen or sulfur atoms or via CO or SO₂ groups; examples thereof are polyphenylene sulfides, polyether sulfones or polyether ketones
aromatic polyesters (polyarylates) or aromatic polyamides (polyaramids); examples thereof are poly-m-phenyleneisophthalamide, poly-p-phenyleneterephthalamide and polyhydroxybenzoate and its copolymers
heterocyclic polymers such as polyimides, polybenzimidazoles or polyether imides.

Foils useful as substrates further include foils composed of electrically conductive polymers. This is to be understood in the context of this description as meaning foils having metallic electric conductivity.

Electrically conductive classes of polymer which may be used with preference are the abovementioned polymers rendered electrically conductive by doping.

The polymers are initially insulators or semiconductors. Electrical conductivity comparable to that of metallic conductors only ensues once the polymers are doped oxidatively or reductively.

Examples of electrically conductive polymers include polyaniline or polyacetylene, the electrical conductivity of which can be appreciably increased by doping with arsenic pentafluoride or with iodine, for example. Further examples of electrically conductive polymers are doped polypyrrole, polyphenylene sulfide, polythiophene and also organometallic complexes with macrocyclic ligands, such as phthalocyanine. Oxidative doping can be achieved with arsenic pentafluoride, titanium tetrachloride, bromine or iodine; reductive doping, by contrast, can be achieved with sodium-potassium alloys or with dilithium benzophenonate.

Preferred embodiments of the coated plastic foil provide one or more of the following features:

The one or more layers deposited by plasma-enhanced thermal electron beam vaporization are preferably acid resistant to at least class 2 of DIN 12116. The reference to DIN 12116 is analogous. The surface to be tested is accordingly boiled in hydrochloric acid (c=5.6 mol/l) for six hours. Subsequently, weight loss in mg/100 cm² is determined. Class 2 is satisfied when half the surface weight loss after six hours is above 0.7 mg/100 cm² and at most 1.5 mg/100 cm². More preferably, class 1 is satisfied when half the surface weight loss after six hours is at most 0.7 mg/100 cm².

Alternatively or additionally, alkali resistance may be provided to class 2, more preferably to class 1, of DIN 52322 (ISO 695). Again the reference is analogous. To determine alkali resistance, the surfaces are exposed to a boiling aqueous solution for three hours. The solution is composed of equal parts of sodium hydroxide (c=1 mol/l) and sodium carbonate (c=0.5 mol/l). The weight losses are determined. Class 2 is satisfied when the surface weight loss after three hours is above 75 mg/100 cm² and at most 175 mg/110 cm². For class 1, the surface weight loss after three hours is at most 75 mg/100 cm².

In one embodiment, the one or more layers deposited by plasma-enhanced thermal electron beam vaporization have a hydrolytic resistance to at least class 2 of DIN 12111 (ISO 719), preferably to class 1.

Solvent resistance may also be provided as an alternative or in addition.

In one preferred embodiment, the layers deposited by plasma-enhanced thermal electron beam vaporization have an internal stress of less than +500 MPa, where the positive sign indicates a compressive stress in the layer. Preferably, an internal stress in the layer is established at from +200 MPa to +250 MPa and also −20 MPa to +50 MPa, where the negative sign indicates a tensile stress in the layer.

In a further preferred embodiment, the composite composed of the plastic foil and barrier layer deposited by plasma-enhanced thermal electron beam vaporization has an oxygen permeability of less than 10° (g/m²*24 h*bar), preferably of less than 10⁻(g/m²*24 h*bar), more preferably of less than 10⁻⁵ (g/m²*24 h*bar) and most preferably of 10⁻⁶ to 10⁻¹⁰ (g/m²*24 h*bar).

In a further preferred embodiment, the composite composed of the plastic foil and barrier layer deposited by plasma-enhanced thermal electron beam vaporization has a water vapor permeability of less than 10⁰ (g/m²*24 h*bar), preferably of less than 10⁻² (g/m²*24 h*bar), more preferably of less than 10⁻⁵ (g/m²*24 h*bar) and most preferably of 10⁻⁶ to 10⁻¹⁰ (g/m²*24 h*bar).

Oxygen and/or water vapor permeability can be determined using instruments from Mocon (www.mocon.com). The determination is carried out in accordance with ASTM F1249.

In one particularly preferred embodiment, the composite composed of a plastic foil and a barrier layer deposited by plasma-enhanced thermal electron beam vaporization is transparent. This is to be understood as meaning in the context of this description that in the wavelength range from 380 nm to 780 nm the composite has a transmissivity for electromagnetic radiation of not less than 80%, preferably not less than 90% and most preferably from 95% to 100% of electromagnetic radiation incident upon a composite surface coated with the barrier layer.

Additionally or alternatively, the layers deposited by plasma-enhanced thermal electron beam vaporization may be made to be scratchproof to a Knoop hardness of at least HK 0.1120=400 as per ISO 9385.

In one embodiment of the invention, the layers deposited by plasma-enhanced thermal electron beam vaporization are very firmly adherent, with lateral forces of above 100 mN, to the plastics surface in a nano-indenter test with a 50 nm tip. Alternatively, the adherence of the vapor-deposited layers can be determined by the tape snap adhesion test or by the cross cut/tape snap adhesion test (to DIN EN ISO 2409).

The process for producing the coating(s) may be adapted in order that one or more of the layer properties mentioned above may be developed.

In a further embodiment of the invention, the plastic foil coated in accordance with the invention is combined with one or more substrates. The substrates may in turn be foils or foil composites, for example plastics foils and/or metal foils, or electric, electronic, optoelectronic, electromechanical or micromechanical components. Combining the foil coated according to the invention with the further foils or components may be effected by adhering, laminating or fusion, for example. The plastic foil coated according to the invention may cover one surface of the further foil or of the further foil composite or both surfaces thereof. The plastic foil coated according to the invention may cover part of the surface of the component or envelop the entire surface of the component. According to the invention, the inorganic vapor-depositable material can also be applied to particularly shaped surfaces which at present can still not be constructed in scratchproof form. This would enable completely new components to be provided in automotive engineering, for example.

The further substrate can be any desired product which has been combined with the plastic foil coated according to the invention. Some preferred embodiments of such composites will now be described using flexible electronics as an example. However, other products may also be combined with the plastic foils coated according to the invention.

Preferably, the plastic foil coated according to the invention may be combined with components selected from the group of semiconductor components, opto-electronic components, electromechanical components and/or micro-mechanical components, or with foil composites representing constituent parts of flexible flat cables or of flexible printed circuits.

The invention preferably relates to a flexible composite comprising a flexible plastic foil (base foil) patterned on one side with electrically conducting material, especially metal, electrically conducting polymer and/or metal-filled polymer, to form a pattern which is combined with electronic components, for example with integrated circuits, transistors, capacitors, resistors and/or inductances, applied to this side and which defines an electronic circuit, and being coated on this side, and optionally on the side remote therefrom, with the composite foil according to the invention so that the side coated with the inorganic vapor deposition material faces outwards. The components with this type of circuit are accessible from one side only. However, holes may be provided in the base foil in order that contact wires for connection with the electronic components may be provided. In addition, flexible circuits of this type can be equipped with dual access. This type of flexible circuit likewise uses a single conducting layer. However, access to selected features of the conductor pattern is possible from both sides.

The invention preferably relates in a further embodiment to a flexible composite comprising a flexible plastics foil (base foil) patterned on both sides with electrically conducting material, especially metal, electrically conducting polymer and/or metal-filled polymer, to form a pattern which is combined with electronic components, for example with integrated circuits, transistors, capacitors, resistors and/or inductances, applied to one or both of the sides and defines an electronic circuit, and being coated on one side, and optionally both sides, with the composite foil according to the invention so that the side coated with the inorganic vapor deposition material faces outwards. Two conductor plies are used in these double-sided flexible circuits. These double-sided flexible circuits can be produced with or without through-plating. The through-plating provides connections for components on both sides of the base foil, so components may be disposed on both sides.

The invention preferably relates in a further embodiment to a flexible composite comprising at least two flexible plastic foils (base foils) each patterned on one or both of the sides with electrically conductive material, especially metal, electrically conducting polymer and/or metal-filled polymer, to form a pattern which is combined with electronic components, for example with integrated circuits, transistors, capacitors, resistors and/or inductances, which are situated on one side of one base foil or on both sides of one base foil or on one or more sides of two or more base foils, and which defines an electronic circuit, and being coated on one side, and optionally both sides, of the composite with the composite foil according to the invention so that the side coated with the inorganic vapor deposition material faces outwards. Two or more conductor plies are used in these multiply layered flexible circuits. These multiply layered flexible circuits are generally provided with through-plating between the individual patterns of electrically conducting material although this is not absolutely necessary. The individual layers of the multiply layered flexible circuit can be constructed, in a continuous or batch manner, by lamination. Batch lamination is customary in cases where a maximum degree of flexibility is required.

The invention preferably relates in a further embodiment to a composite of flexible circuits and of rigid circuits (hybrid construction) which is coated on one side, and optionally on both sides, of the composite with the composite foil according to the invention so that the side coated with the inorganic vapor deposition material faces outwards. This type of flexible circuit embodies a hybrid construction where flexible circuits consisting of rigid and flexible substrates are laminated to each other in a single structure. Rigid flexible circuits must not be confused with stiffened flexible constructions, which are simple flexible circuits where a stiffening element has been secured in order that the weight of the electronic components may be protected on site. The layers in a rigid flexible circuit are normally also electrically connected to each other by through-contacting.

The base foil for producing flexible circuits is a flexible polymeric foil. It offers the foundation ply for a laminate. In normal circumstances, the base foil of the flexible circuit constitutes the vehicle for most of the primary physical and electrical properties of the flexible circuit. In adhesionless constructions of flexible circuits, the base material provides all the characteristic properties. While a multiplicity of thicknesses are possible, most flexible foils are typically used in a range of relatively thin dimensions extending from 5 μm to 500 μm. But thinner or thicker material is also possible. There are a number of different materials the use of which for producing flexible circuits as base foils may be preferable. Examples thereof are polyesters (PET), polyimides (PI), polyethylene naphthalate (PEN), polyether imide (PEI) or various fluoropolymers (FEP).

Flexible circuits can be obtained as multilayered products. This is typically done by lamination. Adhesives may be used as joining medium for the creation of a laminate. Useful adhesives include hot-melt adhesives or thermosets where the adhesive join is formed by curing.

Metal foils are frequently used as conducting element in flexible laminates. A metal foil is the material from which the conductor tracks are normally etched. A multiplicity of metal foils in varying thickness can be used in the production of flex circuits. Copper foils are used for preference.

In a further preferred embodiment, the coated plastic foil according to the invention is used on one or both of the external sides of a laminate of at least one layer of electrically conductive material and at least one plastic foil so that the side coated with the inorganic vapor deposition material faces outwards. The layer of electrically conductive material is preferably constructed in the form of a pattern, especially in the form of mutually parallel conductor tracks, and may optionally be mounted between two plastic foils. Laminates of this type can be used as flat cables.

The present invention also provides a process for producing the coated plastic foils described above.

The process of the present invention comprises:
i) placing a plastic foil having an upper and a lower surface in a vapor deposition apparatus, and
ii) depositing at least one dielectric barrier layer against gases and liquids, especially against oxygen and water vapor, onto at least one of the surfaces by plasma-enhanced thermal vapor deposition of inorganic vapor-depositable material.

Mechanically stable and scratchproof components may be provided by depositing the barrier layer(s).

The process of the present invention can be used to provide foils coated with inorganic vapor-depositable material, especially with glass, which are scratchproof and which can be brought into various shapes which were hitherto impossible with glass. The surface has the constitution of glass, but the shape is independent of the normal constraints which are typically inherent in glass. As a result, components which were hitherto impossible because of material constraints may be produced for automotive engineering and also for trains and for building construction, for example.

The foil composite of the present invention can be used in particular for production of electric, electronic, electro-optical, electromechanical and micromechanical components and also for production of flexible electric connections.

Examples of electric components are flexible generators or stores for electric energy, especially flexible solar cells (flexible photovoltaic cells) or flexible rechargeable batteries.

Examples of electronic components include flexible electronic circuits or flexible circuit boards.

Examples of electro-optical components include flexible displays, especially flexible LCD displays or flexible OLED displays; or flexible light-emitting elements, especially flexible LEDs, flexible OLEDs or flexible laser diodes; or flexible phototransistors.

Examples of electromechanical components include relays, microphones or loudspeakers.

Examples of micromechanical components include sensors or actuators (e.g. relays, switches, valves, pumps) and also microsystems (e.g. micromoters or pushbuttons).

These components may be used in a very wide variety of fields in industries and the home, for example in computers, peripherals, such as printers or keyboards, mobile phones, cameras, personal entertainment devices, jewellery, functional apparel, monitors, automobiles, ships, aircraft, rockets or satellites.

Many circuits comprise structures for passive cabling which may be used for connecting electronic components, such as integrated circuits, resistors, capacitors and the like, or else which are used for establishing connections between different electronic devices, either directly or using plug connectors. The invention also relates to the use of the above-described coated composites in cables for connection of electric, electronic, electro-optical, electromechanical or micromechanical components.

The above description is presented to enable a person skilled in the art to make and use the invention, and is provided in the context of a particular application and its requirements. Various modifications to the preferred embodiments will be readily apparent to those skilled in the art, and the generic principles defined herein may be applied to other embodiments and applications without departing from the spirit and scope of the invention. Thus, this invention is not intended to be limited to the embodiments shown, but is to be accorded the widest scope consistent with the principles and features disclosed herein. In this regard, certain embodiments within the invention may not show every benefit of the invention, considered broadly.

1. A flexible composite barrier against gases and liquids, comprising:
a plastic foil having an upper and a lower surface; and
a dielectric barrier layer on at least one surface of the plastic foil;
wherein
the dielectric barrier layer comprises an inorganic vapor depositable material, and
the dielectric barrier layer is applied directly to the at least one surface of the foil by plasma-enhanced thermal vapor deposition.

2. The flexible composite of claim 1, comprising:
a dielectric barrier layer on each of the upper and lower surfaces;
wherein each of the barrier layers is applied by plasma-enhanced thermal vapor deposition.

3. The flexible composite of claim 1, wherein the inorganic vapor-depositable material of the dielectric barrier layer is selected from the group consisting of aluminum, gold, silver, chromium, nickel, copper, silicon, gallium, alumina, silica, silicon nitride, silicon carbide, titania, zirconia, indium-tin oxide, fluorine-doped tin oxide, indium-gallium-tin oxide, cadmium telluride, copper-indium-gallium-selenium-sulfur compounds and a vapor-depositable glass material.

4. The flexible composite of claim 3, wherein the inorganic vapor-depositable material of the dielectric barrier layer is a vapor-depositable glass material and the vapor-depositable glass material is a silicate glass,

5. The flexible composite of claim 4, wherein the silicate glass is a borosilicate glass.

6. The flexible composite of claim 1, wherein a thickness of the dielectric barrier layer is from 50 nm to 100 μm.

7. The flexible composite of claim 1, wherein the plastic foil is a thermoplastic plastic or a thermoset plastic.

8. The flexible composite of claim 1, wherein the plastic foil is a transparent plastic.

9. The flexible composite of claim 7, wherein the plastic foil is a thermoplastic plastic which is selected from the group consisting of a polyolefin, a polyvinyl halide, a polyvinylidene halide, a polyvinylaromatic, a polyacrylic ester, a polymethacrylic ester, a polyvinyl ether, a polyvinylcarboxylic ester, a polytetrahaloethylene, an acrylonitrile homo-or copolymer, a polyoxymethylene homo- or copolymer, a polyamide, a polyester, a polycarbonate, a polyurethane, a polyalkylene glycol and a poly(organo)siloxane.

10. The flexible composite of claim 7, wherein the plastic foil is a thermoplastic plastic which is a high temperature resistant plastic which is selected from the group consisting of a fluoropolymer, a polyphenylene, a polyaryl having aromatic rings linked via an oxygen atom, a sulfur atom, a CO group or a SO₂ group, an aromatic polyester, an aromatic polyamide and a heterocyclic polymer.

11. The flexible composite of claim 10, wherein the thermoplastic plastic is a heterocyclic plastic which is selected from the group consisting of a polyimide, a polybenzimidazole and a polyether imide.

12. The flexible composite of claim 7, wherein the plastic foil is a thermoplastic plastic which is selected from the group consisting of polyethylene terephthalate, polyethylene naphthalate, polybutylene terephthalate, a polycarbonate, a polyacrylonitrile and a polyimide.

13. The flexible composite of claim 1, wherein an oxygen permeability is less than 10⁰ g/m² *24 h*bar and/or a water vapor permeability is less than 10⁰ g/m²*24 h*bar.

14. The flexible composite of claim 1, wherein a transmissivity for electromagnetic radiation in the wavelength range from 380 nm to 780 nm is not less than 80% of electromagnetic radiation incident upon a composite surface coated with the dielectric barrier layer.

15. The flexible composite of claim 1, further comprising a substrate which is selected from the group consisting of a foil, a foil composite, an electric component, an electronic component, an optoelectronic component, an electromechanical component and a micromechanical component.

16. A component comprising the flexible composite of claim 1, wherein the component is selected from the group consisting of a semiconductor component, an opto-electronic component, an electromechanical component, a micromechanical component, a flexible flat cable and a flexible printed circuit.

17. An electronic component comprising the flexible composite of claim 1, wherein the flexible plastic foil is patterned on one side with an electrically conducting material to form a pattern which is combined with the electronic component applied to the patterned side and which defines an electronic circuit, and optionally coated on the side remote therefrom with the flexible composite foil of claim 1 so that in each coating, the inorganic vapor deposition material faces outward.

18. An electronic component comprising the flexible composite of claim 1, wherein the flexible plastic foil is patterned on both sides with an electrically conductive material to form a pattern which is combined with the electronic component being applied to one or both of the sides and defines an electronic circuit, and being coated on one side, and optionally both sides, so that the inorganic vapor deposition material faces outward.

19. An electronic component unit comprising the flexible composite of claim 1, wherein the flexible composite comprises at least two flexible plastics foils each patterned on one or both of the sides with electrically conductive material to form a pattern which is combined with electronic components which are situated on one side of one flexible plastic foil or on both sides of one flexible plastic foil or on one or more sides of two or more plastic foils, and which define an electronic circuit, and being coated on one side, and optionally both sides so that the side coated with the inorganic vapor deposition material faces outward.

20. A composite of flexible circuits and of rigid circuits which is coated on one side, and optionally on both sides, of the composite with the flexible composite foil of claim 1 so that the inorganic vapor deposition material faces outward.

21. A laminate comprising a layer of electrically conductive material and at least one flexible composite of claim 1, arranged so that the inorganic vapor deposition material faces outward.

22. A process for producing a flexible composite of claim 1, comprising:
placing a plastic foil having an upper and a lower surface in a vapor deposition apparatus, and
depositing at least one dielectric barrier layer against gases and liquids onto at least one of the surfaces by plasma-enhanced thermal vapor deposition of an inorganic vapor-depositable material.

23. An electric component comprising the flexible composite of claim 1, wherein the electric component is selected from the group consisting of an electronic component, an electro-optical component, an electromechanical component, a micromechanical component and a flexible electric connection.

24. An electric unit comprising the electric component of claim 23, wherein the unit is a flexible generator or store for electric energy.

25. The electric unit of claim 24, wherein the electric unit is a flexible solar cell or a flexible rechargeable battery.

26. An electric unit comprising the electric component of claim 23, wherein the unit is a flexible electronic circuit or a flexible circuit board.

27. The electric unit of claim 23 which is an electro-optical component and which is selected from the group consisting of a flexible display, a flexible LCD display, a flexible OLED display, a flexible light-emitting element, a flexible LED, a flexible OLED, a flexible laser diode and a flexible phototransistor.

28. The electric unit of claim 23 which is an electromechanical component which is a relay, a microphone or a loudspeaker.

29. The electric unit of claim 23 which is a micromechanical component which is selected from the group consisting of a sensor, an actuator, a relay, a switch, a valve, a pump, a microsystem, a micromotor and a pushbutton.

30. A product comprising the electric unit of claim 23, wherein the product is selected from the group consisting of a computer, a computer peripheral, a mobile phone, a camera, a personal entertainment device, jewellery, functional apparel, a monitor, an automobile, a ship, an aircraft, a rocket and a satellite.

31. A connection cable comprising the flexible composite of claim 1, wherein the cable is suitable for connection of electric, electronic, electro-optical, electromechanical or micromechanical components.
